(19) United States
(12) Patent Application Publication
(10) Pub. No.: US 2025/0028892 A1
(43) Pub. Date: Jan. 23, 2025

(54) PHYSICALLY OBFUSCATED CIRCUIT

(71) Applicant: Infineon Technologies AG, Neubiberg (DE)

(72) Inventor: Stefan Seidl, Unterhaching (DE)

(21) Appl. No.: 18/779,386

(22) Filed: Jul. 22, 2024

(30) Foreign Application Priority Data
Jul. 20, 2023 (DE) 102023206885.0

(51) Int. Cl. G06F 30/39

(52) U.S. Cl. CPC G06F 30/39

(57) ABSTRACT

Physically obfuscated circuit including subcircuits each having: series-connected transistors of a first conductivity; a transistor of a second conductivity; wherein the transistors are connected such that the series-connected transistors, if supplied with a first reference potential at their respective control terminal, deliver a second reference potential different from the first reference potential to the control terminal of the transistor of the second conductivity; and the transistor of the second conductivity, if supplied with a second reference potential at its control terminal, delivers the first reference potential to the control terminal of each of the series-connected transistors; and a precharge circuit to precharge the subcircuit to a first state in which the potential at the control terminal of the transistor of the second conductivity is different from the second reference potential and the potential at the control terminal of each of the series-connected transistors is different from the first reference potential.

### TECHNICAL FIELD

The invention relates to a physically obfuscated circuit.

### BACKGROUND

Piracy and reverse engineering (RE) of integrated circuits (ICs) are considered to be one of the most serious threats to the semiconductor industry, as they are able to be misused to steal and/or pirate a design: successful attackers are able to overbuild or fabricate ICs and sell similar, that is to say “cloned” ICs, and they are able to illegally use or sell the extracted and stolen IP and sell competitors' trade secrets, etc. For all these reasons, it is desirable to develop concepts and techniques that prevent IC piracy and reverse engineering.

### BRIEF DESCRIPTION OF THE DRAWINGS

Exemplary embodiments of the invention are illustrated in the figures and are explained in more detail below.

In the figures:

FIG. 1 shows a chip card as an example;

FIG. 2 shows a TIE cell;

FIG. 3 shows a POC cell with two TIE cells;

FIG. 4 shows a timing diagram for the POC cell from FIG. 3;

FIG. 5 shows another POC cell, which may be considered to be a variant of the POC cell from FIG. 3;

FIG. 6 shows a POC cell according to another example;

FIG. 7 shows a timing diagram for the POC cell from FIG. 6;

FIG. 8 shows a POC cell, which may be the CMOS complement of the POC cell from FIG. 3;

FIG. 9 shows a timing diagram for the POC cell from FIG. 8;

FIG. 10 shows a physically obfuscated circuit according to one embodiment.

### DETAILED DESCRIPTION

The following detailed description refers to the accompanying drawings, which show specific details and aspects of this disclosure for illustrative purposes with regard to how the invention is able to be implemented. Other aspects may be used and structural, logical and electrical modifications may be made without departing from the scope of protection of the invention. The various aspects of this disclosure are not necessarily mutually exclusive, since some aspects of this disclosure may be combined with one or more other aspects of this disclosure in order to form new aspects.

For the purposes of this description, the terms “connected” and “coupled” are used to describe both a direct and an indirect connection and a direct or indirect coupling. Identical or similar elements are provided with the same reference signs in the figures, where appropriate.

One promising approach with regard to reliably and securely identifying and authenticating ICs is that of using what are known as physically random functions or physically obfuscated circuits (POCs) to securely generate on-chip secret keys for cryptographic algorithms. Ideally, silicon POCs generate chip-specific keys that are arbitrarily repeatable, but are not predictable and cannot be determined externally. This may be achieved by utilizing random variations of IC manufacturing processes and at the same time suppressing global process, temperature and supply voltage variations and noise.

Since these POCs may be integrated together on the chip with dedicated control logic, any attempt to physically access the POC circuit arrangement itself is able to be limited very effectively and efficiently. This significant resistance to physical attacks is the main advantage of using controlled silicon POCs.

In addition, only weak POCs are needed to generate secret keys, that is to say POCs that generate POC values for only a limited number of challenge-response pairs (compared to other possible challenge-response pairs).

A POC value P may be thought of as a kind of fingerprint of a physical object. The physical object is able to be uniquely identified by way of the true POC value P, that is to say the POC value when it is registered, and a key may for example be produced based on the identification. The physical object may be a controller or a microcontroller. It may also be a chip card IC (integrated circuit) of a chip card, such as for instance a smart card with any form factor, for example for a pass or for a SIM (subscriber identity module).

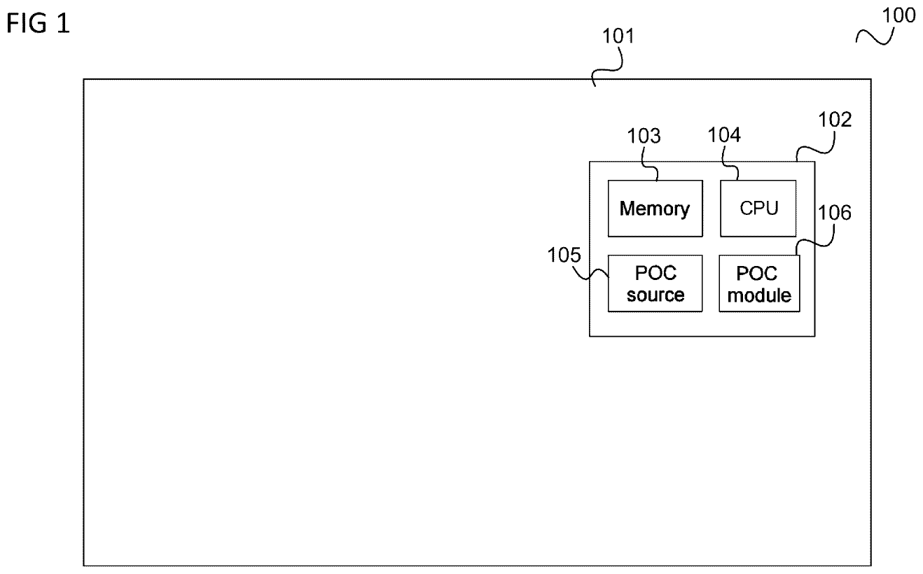

FIG. 1 shows a chip card 100 as an example.

The chip card 100, which is illustrated here in the card format, but may have any form factor, has a carrier 101 and a chip card module 102. The chip card module 102 has various components, such as for instance a non-volatile memory 103 and a CPU (central processing unit) 104. In various embodiments, the chip card has a component 105 that serves as a POC source, for example a circuit including multiple subcircuits, wherein an output of a subcircuit specifies one or more bits of a POC value (or is used as a basis for this). It should be noted that the chip card 100 using a POC is only an example, and may be a device including any kind of integrated circuit.

The POC value P may be considered to be an identification number for the chip card 100 (more precisely for the chip card module 102 in the chip card 100). By way of example, the chip card module 102 has a cryptoprocessor that derives an individual cryptographic key for a chip card 100 from this identification number, or the CPU 104 itself derives a cryptographic key therefrom.

For security reasons, neither the true POC value P nor the cryptographic key derived therefrom are stored on the chip card 100. Instead, what is known as a POC module 106 is located on the chip card 100 and connected to the physical object 105. If the POC value P is required (for example for key generation), then what is known as a POC request is made to the POC module 106, in response to which the POC module 106 determines the POC value again in each case (by way of an internal electronic operation). In other words, the POC module 106 responds to a POC request with the output of a POC value P′, which may deviate to a greater or lesser extent from the true POC value P, that is to say from the POC value upon registration thereof, depending on the bit stability of the bits provided by POC source 105.

There are various approaches to implementing controlled silicon-based POCs (that is to say POC sources 105), for example SRAM-based, read-amplifier-based, butterfly-based and latch-based POC arrays, on the one hand, and delay-based POCs, such as for instance ring oscillator POCs and arbiter POCs, on the other hand.

Approaches such as SRAM-POCs (based on the tendency of single-bit cells, induced by process variations, to preferably assume one of their two stable states at switch-on) typically suffer from severe limitations, such as for instance poor bit stability and high susceptibility to semi-invasive attacks, such as for instance electrical and optical probing, and/or inappropriate statistical quality.

With regard to delay-based POCs, such as ring oscillator (RO) and arbiter POCs (which compare the delays of two ideally identically implemented delay lines), there are similar limitations in terms of bit stability and statistical quality, whereas their known weakness to model-building attacks is irrelevant for cryptographic on-chip key generation because the very low number of controlled silicon POC challenge-response pairs is never directly exposed and cannot be determined externally.

The implementation of silicon arbiter POCs typically leads to relatively poor statistical quality and POC bit stability, since irregular placement and automated routing of the elements of the arbiter POC leads to asymmetric wiring and consequently to systematic delay distortions, that is to say poor statistical quality, on the one hand. On the other hand, the delay differences between the two paths with the same nominal layout length depend only on the small process variations of the gates involved and the wiring, which represent the competing delay paths, leading to poor bit stability. This in turn necessitates the generation of what are known as helper data during a POC entry, that is to say together with an initial key generation, as well as error correction that is expensive and time-consuming (in terms of numbers of gates and footprint as well as energy dissipation) during a key reconstruction in the field.

By way of example, POC bit stability may be increased by what is known as stable bit marking or by pre-selecting POC bits (as a result of which non-stable bits are discarded upon an entry and are no longer taken into account during a reconstruction).

A description is given below of approaches for implementing a secure and cost-effective POC, for example for generating secret keys, which exhibits significantly improved security against physical attacks and exhibits reproducibility that is so high that no error correction is necessary (which is a considerably expensive measure and is typically indispensable for conventional POCs).

These features are achieved by way of a POC circuit arrangement that utilizes extremely nonlinear electrothermal depth subthreshold relaxation processes from non-equilibrium states to limited-equilibrium states.

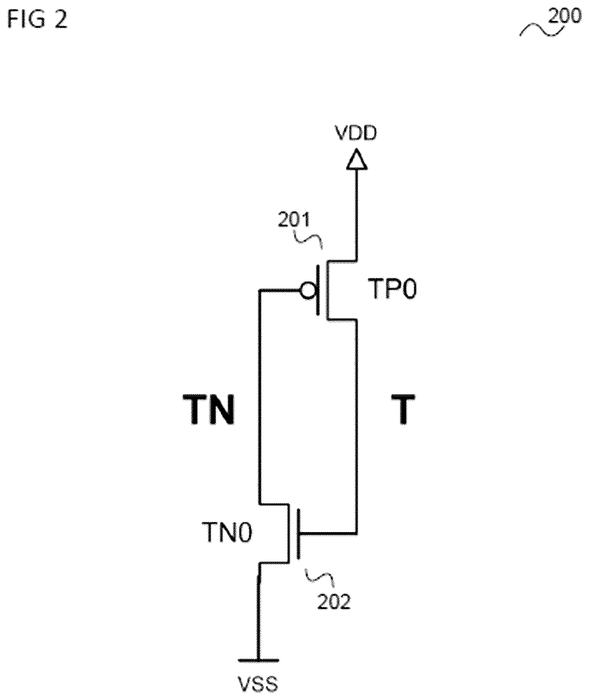

In particular, the POC source 105 is based, according to various embodiments. on what are known as TIE cells, as illustrated in FIG. 2.

FIG. 2 shows a TIE cell 200.

The TIE cell 200 contains a p-channel field-effect transistor (FET) 201, the source of which (as an example of a controlled terminal) is connected to a high supply potential (for example VDD), the gate of which (as an example of a control terminal) is connected to the drain of an n-channel field-effect transistor 202, and the drain of which (as an example of a further controlled terminal) is connected to the gate of the n-channel field-effect transistor 202. The source of the n-channel field-effect transistor 202 is connected to a low supply potential (for example VSS). It should be noted that all of the FETs mentioned here may for example be MOSFETs (metal-oxide-semiconductor field-effect transistors) and may be formed using CMOS (complementary MOS) technology.

The node (or the connection) connecting the gate of the p-channel field-effect transistor 201 to the drain of the n-channel field-effect transistor 202 is hereinafter referred to as TN, and the node (or the connection) connecting the gate of the n-channel field-effect transistor 202 to the drain of the p-channel field-effect transistor 201 is hereinafter referred to as T. Hereinafter, for ease of simplicity, the state of a node is referred to by the name of the node, for example T also refers to the state (or the signal) at the node T.

First of all, the case of limited electrothermal equilibrium is assumed. It will be assumed that the difference in supply potential VDD-VSS is high enough that, in a steady-state equilibrium, the two FETs 201, 202 operate with strong inversion (that is to say they have a fully developed channel inversion):

VDD−VSS>Vth(n-channel FET 202)+|Vth(p-channel FET 201)|
wherein Vth (FET) denotes the threshold voltage of the FET indicated in parentheses.

The expected values of the node voltage are then the steady-state values V(T)=VDD and V(TN)=VSS. In other words, even for time-variable voltages VDD and VSS, the time-averaged values are the steady-state (and time-averaged) values V(T)=VDD and V(TN)=VSS given above.

In addition, the relaxation time of the circuit ranges from a few 100 ps to the nanosecond regime, depending on the process technology, the supply voltage and the temperature. In other words, the potentials V(T) and V(TN) relax from small disturbances (deviations from their steady-state values) to their steady-state values VDD and VSS with relaxation times in the (sub) nanosecond regime.

However, large deviations of V(T) and V(TN) from their equilibrium values result in a completely different behavior of the TIE cell circuit components. In particular, consideration is given to the extreme case of the following initial condition:

V(T)=VSS and V(TN)=VDD at the time t=0.

In other words, the node voltages are initially kept at the “inverse” values relative to their above equilibrium values, so that the two FETs 201, 202 are initially switched OFF, that is to say they are both in their deep subthreshold domain.

If the initial condition is then released for t>0 (that is to say the nodes T and TN are no longer forced to their initial values), the circuit arrangement 200 is initially in a non-equilibrium state, namely in a state as far away as possible from its steady state described above. As a result, the potentials of the nodes T and TN move in the direction of their equilibrium (steady-state) values V(T)=VDD and V(TN)=VSS due to unavoidable (deep) subthreshold currents. However, the transition is an extremely nonlinear transition that depends strongly on the VDD voltage level relative to VSS, on the temperature T and in particular on the unavoidable manufacturing process variations for the circuit components (here FETs 201, 202), and so two instances (copies) of the “same” TIE cell are very likely to differ in terms of their relaxation times.

According to various embodiments, two (or more than two, see the examples described below) copies of circuits exhibiting the above TIE cell behavior upon relaxation from a state far from equilibrium are used for a POC circuit arrangement. Such circuits are particularly suitable for a POC circuit arrangement due to the extremely wide statistical distribution of depth subthreshold relaxation times owing to manufacturing variations.

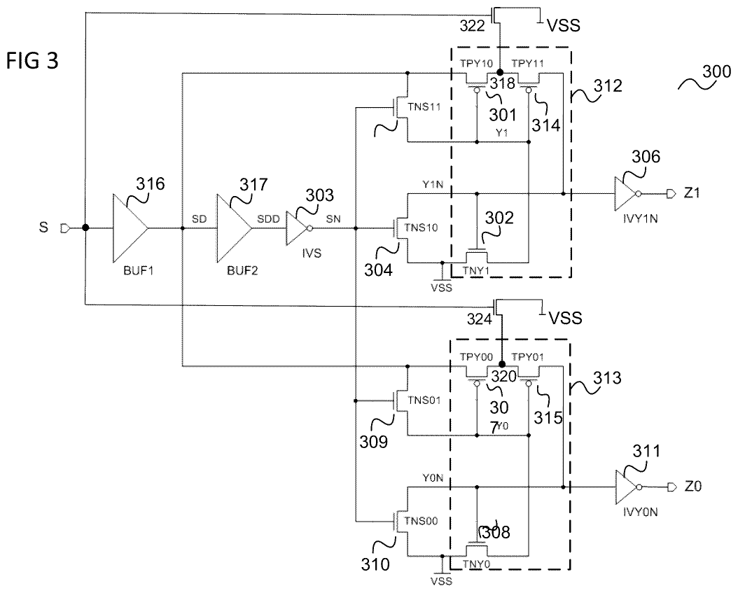

In particular, a dedicated circuit arrangement based on the depth subthreshold TIE cell relaxation described above from non-equilibrium states far from their steady states is introduced (such as for example in the POC source 105), as illustrated for example in FIG. 3.

FIG. 3 shows a POC cell 300.

Like all of the POC cells described here, multiple POC cells 300 may be contained in a circuit configured to generate one or more POC values, for example the POC source 105.

The POC cell 300 contains a first TIE cell 312. The first TIE cell 312 has a series connection consisting of a first p-channel FET 301 and a second p-channel FET 314, and a first n-channel FET 302. The first p-channel FET 301 and the second p-channel FET 314 are cross-coupled to the first n-channel FET 302 and connected to VDD and VSS, respectively, as explained with reference to FIG. 2, but the p-channel FET 201 there is replaced with a series connection of the first p-channel FET 301 and the second p-channel FET 314. The POC cell 300 also additionally contains a first precharge control circuit arrangement for the first TIE cell 312, which is formed by a second n-channel FET 304 and a third n-channel FET 305.

The POC cell 300 furthermore optionally has an input inverter 303 and a first buffer 316 and a second buffer 317 that are arranged in series between an input S and the first precharge control circuit arrangement and a second precharge control circuit arrangement (which will be explained in more detail below).

The output of the first buffer 316 (which is connected to an input of the second buffer 317) is connected to the series connection of the p-channel FETs 301, 314 of the first TIE cell (in particular to the source of the first FET 701 in the series) and to the series of p-channel FETs 307, 315 of the second TIE cell (in particular the source of the third p-channel FET 307 in the series connection).

The first buffer 316 receives the control input signal S (hereinafter also referred to as control input S) and buffer-stores it. On the output side, the first buffer 316 provides a first buffered control input signal SD to an input of the second buffer 317. The second buffer 317 receives the first buffered control input signal SD (which is thus time-delayed in relation to the control input signal S) from the first buffer 316 and likewise buffer-stores it. On the output side, the second buffer 317 provides a second buffered control input signal SDD (which is thus additionally time-delayed in relation to the control input signal S) at an input of the input inverter 303. The input inverter 303 receives the second buffered control input signal SDD from the second buffer 317 and inverts it to form an inverted control signal SN, which it delivers to the gate of the second n-channel FET 304 and to the gate of the third n-channel FET 305.

The drain of the second n-channel FET 304 is connected to the source of the first p-channel FET 301, and its source is connected to the gate of the first p-channel FET 301 and to the gate of the second p-channel FET 314. The source of the third n-channel FET 305 is connected to the source of the first n-channel FET 302, and its drain is connected to the gate of the first n-channel FET 302.

The drain of the second p-channel FET 314 is also connected to an input of a first output inverter 306, the output Z1 of which is one of the outputs of the POC cell 300. The drain of the third n-channel FET 305 is likewise connected to the input of a first output inverter 306.

The POC cell 300 also contains a second TIE cell 313. The second TIE cell 313 has a series connection consisting of a third p-channel FET 307 and a fourth p-channel FET 315, and a fourth n-channel field-effect transistor 308. The third p-channel FET 307 and the fourth p-channel FET 315 are cross-coupled to the fourth n-channel field-effect transistor 308 and connected to VDD and VSS, respectively, as explained with reference to FIG. 2, but the p-channel FET 201 there is replaced with a series connection of the third p-channel FET 307 and the fourth p-channel FET 315. The POC cell 300 also additionally contains a second precharge control circuit arrangement for the second TIE cell 313, which is formed by a fifth n-channel FET 309 and a sixth n-channel FET 310.

The gate of the fifth n-channel FET 309 receives the inverted control input signal SN. The inverted control signal SN is also delivered to the gate of the sixth n-channel FET 310.

The drain of the fifth n-channel FET 309 is connected to the source of the third p-channel FET 307, and its source is connected to the gate of the third p-channel FET 307 and to the gate of the fourth p-channel FET 315.

The source of the sixth n-channel FET 310 is connected to the source of the fourth n-channel FET 308, and its drain is connected to the gate of the fourth n-channel FET 308.

The drain of the fourth p-channel FET 315 is also connected to an input of a second output inverter 311, the output Z0 of which is another of the outputs of the POC cell 300. The drain of the sixth n-channel FET 310 is likewise connected to the input of the second output inverter 311.

The nodes TN and T of the first TIE cell 312 are denoted Y1 and YIN, respectively. The nodes TN and T of the second TIE cell 313 are denoted Y0 and Y0N, respectively.

The POC cell 300 may be used (for example in the POC source 105) to generate one bit of a POC value. It may therefore also be referred to as a POC bit cell. As explained, it has two subcircuits, each containing a TIE cell 312, 313 and a precharge circuit arrangement for forcing and releasing the non-equilibrium initial condition.

If the control input S is set to logic “0” (that is to say the VSS level), the first precharge circuit arrangement and the second precharge circuit arrangement (for the two TIE cells 312, 313) force TIE cell initial conditions

V(Y1)=VDD,V(Y1N)=VSS, and

V(Y0)=VDD,V(Y0N)=VSS,

since all of the precharge transistors 304, 305, 309, 310 for the TIE cell nodes Y1, Y1n and Y0, Y0N are then in their respective ON states (wherein the FETs 304, 305, 309, 310 are in strong inversion mode).

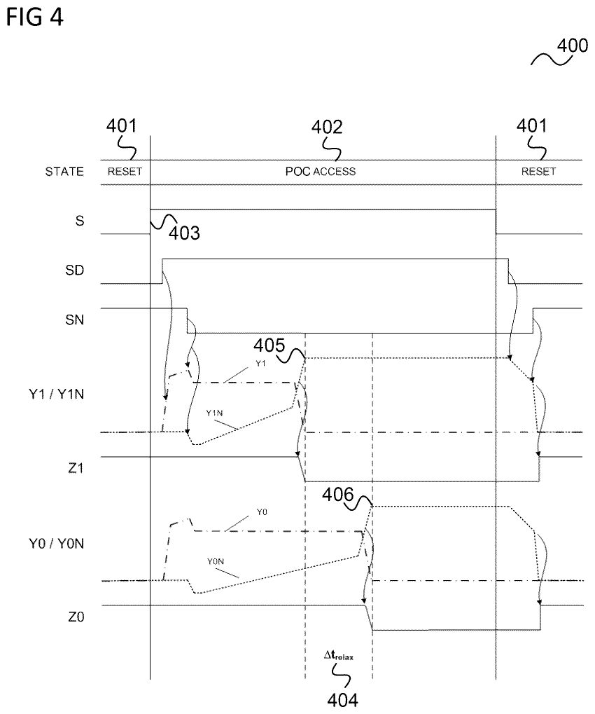

FIG. 4 shows a timing diagram 400 of a precharge and subsequent relaxation (that is to say a precharge and relaxation process sequence) for the POC cell 300 from FIG. 3.

The signals S, Y1, Y1N, Y0, Y0N, Z1, Z0 are shown with time going from left to right (wherein, in each case, a line further toward the top represents a higher potential (for example equal or close to the high operating potential VDD) and a line further toward the bottom represents a lower potential (for example equal or close to the low operating potential VSS)).

First of all, the precharge circuit arrangement for the two TIE cells 312, 313 forces the TIE cell initial conditions

V(Y1)=VDD,V(Y1N)=VSS,

V(Y0)=VDD,V(Y0N)=VSS.

This state is referred to as the reset state 401 or else as the initial state. The control input S is then set to logic “1” (denoted by reference sign 403), thereby initiating a POC access state 402. Following the POC access, the control input S is reset to logic “0”, causing the circuit to return to its reset state 401.

The extremely nonlinear relaxation from the deep subthreshold non-equilibrium state of the nodes Y1, Y1N and Y0, Y0N after the restrictions with S=logic “1” (that is to say during the POC access phase 402) have been released is illustrated in FIG. 4.

Due to production variations of the relevant FETs 301, 314, 302 of the first TIE cell 312 and of the FETs 307, 315, 308 of the second TIE cell 313, the electrothermal relaxations of Y1, Y1N and Y0, Y0N usually differ significantly in terms of their relaxation times (also in a manner strongly dependent on (VDD-VSS) and temperature, to an order of magnitude of a few ns to several μs). As a result, the output signals Z1 and Z0 switch to logic “1” at different times.

This is indicated in FIG. 4 by a time difference 404, which is denoted ΔtRelax and specifies the difference between the time 405 when the first TIE cell 312 reaches its steady state (Z1 switches to logic “1”) and the time 406 when the second TIE cell 313 reaches its steady state (Z0 switches to logic “1”).

Since the geometric dimensions (that is to say gate lengths and gate widths) of the TIE cell components 301, 314, 302, 307, 315, 308 may be selected so as to be very small, they are able to be made extremely sensitive to manufacturing process variations. This extreme variation sensitivity of the TIE cells 312, 313 is typically great enough to enable very effective stable bit marking, as it is known, or customizable preselection of POC bits having a predetermined minimum bit stability, even with regard to environmental variations (such as temperature and supply voltage) and ageing.

A first connection node 318 between the two series-connected first p-channel FET 301 and second p-channel FET 314 of the first TIE cell 312 is a floating node with an undefined electrical potential. Furthermore, a second connection node 320 between the two series-connected third p-channel FET 307 and fourth p-channel FET 315 of the second TIE cell 313 is also a floating node with an undefined electrical potential. These undefined electrical potentials increase the error rate within the POC cell 300.

If for example only the transistor widths were to be adapted in order to increase stability, then the TIE cells 312, 313 would become very slow in some operating ranges.

According to various aspects of this disclosure, in order to reduce the error rate in the POC cell 300 in one or both TIE cells 312, 313, provision is made for a discharge circuit 322, 324, by way of which the previously undefined electrical potential at the first connection node 318 is fixed to a predetermined or predefined reference potential (for example the lower reference potential VSS, for example ground potential) during the precharge state of the POC cell 300.

By way of example, the first TIE cell 312 thus has a first discharge circuit 322 that is connected to the first connection node 318, on the one hand, and to the low reference potential VSS, on the other hand, and is configured for the controlled discharge of electric charge from the first connection node 318. The first discharge circuit 322 has a first discharge transistor (for example an n-FET) 322 or is formed thereby, the drain of which is connected (for example directly) to the first connection node 318 and the source of which is connected (for example directly) to the low reference potential VSS. The control terminal (for example gate) of the first discharge transistor 318 is connected (for example directly) to the input S and is driven by way of the control input S. The first discharge circuit 322 thus by way of illustration forms a switch that is closed during the precharging process of the POC cell 300, and electric charge located on the first connection node 318 is thus discharged to the low reference potential VSS. When the precharging process is complete, the switch is opened again, that is to say for example the first discharge transistor 322 is blocked and thus the first connection node 318 is electrically disconnected, for example isolated, from the low reference potential VSS.

By way of example, the second TIE cell 313 also has a second discharge circuit 324 that is connected to the second connection node 330, on the one hand, and to the low reference potential VSS, on the other hand, and is configured for the controlled discharge of electric charge from the second connection node 320. The second discharge circuit 324 has a second discharge transistor (for example an n-FET) 324 or is formed thereby, the drain of which is connected (for example directly) to the second connection node 320 and the source of which is connected (for example directly) to the low reference potential VSS. The control terminal (for example gate) of the second discharge transistor 320 is connected (for example directly) to the input S and is driven by way of the control input S. The second discharge circuit 324 thus by way of illustration likewise forms a switch that is closed during the precharging process of the POC cell 300, and electric charge located on the second connection node 320 is thus discharged to the low reference potential VSS. When the precharging process is complete, the switch is opened again, that is to say for example the second discharge transistor 324 is blocked and thus the second connection node 320 is electrically disconnected, for example isolated, from the low reference potential VSS.

As an alternative, the control terminals (for example gates) of the discharge transistors 322, 324 may also be connected to a separate terminal (that is to say not to the input S) and be driven by way of another control signal, but in such a way that the discharge transistors 322, 324 are closed during the precharging process and thus electrically conductively connect the respective connection node 318, 320 to the low reference potential VSS, and are open during normal operation (that is to say for example when generating a cryptographic secret key) and accordingly electrically isolate the respective connection node from the low reference potential.

During the precharging process, the control input S is logic “1” (by way of illustration a high-level signal, for example 5 V). The first discharge transistor 322 and the second discharge transistor 324 are thus switched on, and possible electric charges located on the first connection node 318 and the second connection node 320 are discharged to the low reference potential VSS (for example ground potential). In other words, the respective connection node 318, 320 is electrically conductively connected to the low reference potential VSS. In this case, the signal SN provided by the input inverter 303 is logic “0” (by way of illustration a low-level signal, for example 0 V). The second n-channel FET 304 and the third n-channel FET 305 of the first precharge control circuit arrangement are thus blocked, and the first TIE cell 312 is thus deactivated. Furthermore, the fifth n-channel FET 309 and the sixth n-channel FET 310 of the second precharge control circuit arrangement are likewise blocked, and the second TIE cell 313 is thus also deactivated.

As soon as the POC cell 300 is intended to be started in order to generate a secret (for example a cryptographic secret key), the control input S is set to logic “0” (by way of illustration a low-level signal, for example 0 V). The first discharge transistor 322 and the second discharge transistor 324 are thus electrically switched off and the first connection node 318 and/or the second connection node 320 are/is electrically isolated from the low reference potential VSS (for example ground potential). In other words, the respective connection node 318, 320 is electrically isolated from the low reference potential VSS.

In this case, the signal SN provided by the input inverter 303 is logic “1” (by way of illustration a high-level signal, for example 5 V). The second n-channel FET 304 and the third n-channel FET 305 of the first precharge control circuit arrangement are thus switched on, and the first TIE cell 312 is thus activated. Furthermore, the fifth n-channel FET 309 and the sixth n-channel FET 310 of the second precharge control circuit arrangement are likewise switched on, and the second TIE cell 313 is thus also activated. However, the signal SN provided by the input inverter 303 is time-delayed with respect to the control input S (by the first buffer 316 and the second buffer 317 and the input inverter 303) before the signal SN starts to generate the secret by way of the TIE cells 312, 313. This delay is dimensioned to be long enough for the first discharge transistor 318 and the second discharge transistor 320 to have enough time to terminate their respective switch-off operation.

Again with reference to FIG. 4, the signals SD (output of the first buffer 316) and SN (output of the input inverter 303) are also shown.

The buffers 316, 317, together with the input inverter 303 and the n-channel FETs 304, 305, 309, 310, by way of illustration form a circuit arrangement for forcing and releasing the non-equilibrium initial condition.

If the control input S is set to logic “0” (that is to say for example the VSS level, for example by a corresponding controller, for example the POC module 106), the TIE cell initial conditions

V(Y1)=VSS,V(Y1N)=VSS,

V(Y0)=VSS,V(Y0N)=VSS,
are then forced, since the upper supply voltage (for example high reference potential VDD in FIG. 3) of the TIE cells 312, 313 is replaced with SD=logic “0”, and all of the precharge transistors 304, 305, 309, 310 for the TIE cell nodes Y1, Y1N and Y0, Y0N are in their respective ON states (strong inversion).

This reset state 401 is indicated in FIG. 4 as the initial state before the control input S is set to logic “1”, as a result of which the POC access is initiated. The POC access signal is then reset to logic “0”, causing the circuit to return to its reset state.

The POC access is initiated on the rising edge 403 by the control input S (S=logic “0”->logic “1”), as a result of which first SD, which is the upper supply of the TIE cells 312, 313, changes to logic “1” (that is to say the VDD level), such that the nodes Y1 and Y0 are stepped up to voltage levels of approximately VDD−Vth(n-channel FET 304), respectively VDD−Vth(n-channel FET 309), via the n-channel FETs 304, 309. Shortly afterwards, the signal SN changes to logic “0” and switches off the precharge transistors 304, 305, 309, 310 for the TIE cell nodes Y1, Y1N and Y0, Y0N, as a result of which the node voltages thereof drop slightly by a difference ΔVcc, respectively a difference ΔVcc′, due to capacitive coupling of the signal SN.

The relaxation of the node pairs Y1, Y1N and Y0, Y0N then takes place: Y1 and Y0 start from ((VDD−Vth)(n-channel FET 304)−ΔVcc), respectively ((VDD−Vth)(n-channel FET 309)−ΔVcc), and Y1N and Y0N start from (VSS−ΔVcc′). This first leads to generally smaller relaxation times (since the n-channel FETs 301, 314 and the n-channel FETs 307, 315 start in a comparatively less deep subthreshold state).

Negative feedback with reference to temperature variations is also implemented: since Vth(n-channel FET 304) and Vth(n-channel FET 309) increase as the temperature decreases, the starting values of the voltages at the nodes Y1 and Y0 decrease at lower temperatures, thereby increasing the relaxation speed and counteracting the decrease in the relaxation speed due to higher threshold voltages of the n-channel FETs 301, 314, 302 and 307, 315, 308.

The extremely nonlinear relaxation from the deep subthreshold non-equilibrium state of the nodes Y1, Y1N and Y0, Y0N after the restrictions with S=logic “1” (that is to say during the POC access phase 402) have been released is indicated in FIG. 4.

Due to production variations of the relevant transistors 301, 314, 302 (of the first TIE cell 312) and of the transistors 307, 315 and 308 (of the second TIE cell 313), the electrothermal relaxations of Y1, Y1N and Y0, Y0N usually differ significantly in terms of their relaxation times (to an order of magnitude of a few ns to several 10 ns). As a result, the output signals Z1 and Z0 change to logic “1” at different times, this being indicated by a time difference 404, which is indicated as ΔtRelax in FIG. 4.

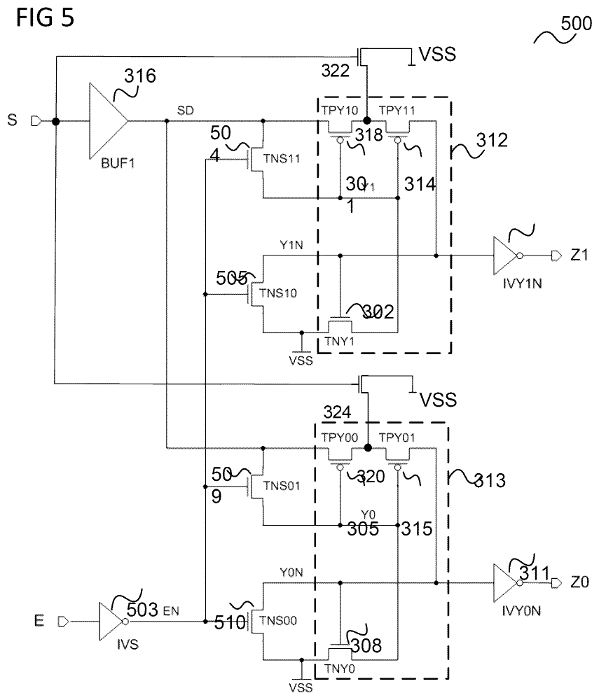

FIG. 5 shows another POC cell 500, which may be seen as a variant of the POC cell 300 from FIG. 3.

The POC cell 500 differs from the POC cell 300 from FIG. 3 in that the input inverter 503 does not receive its input signal via a second buffer 317, but receives an activation signal E (and accordingly generates a signal EN instead of SN in FIG. 3).

Accordingly, the sole difference from FIG. 3 is the decoupling of the timing of S and SN, which enables an adjustable starting level of the voltages of the nodes Y1 and Y0 by introducing a second input control signal E that is inverted to form EN and controls the switch-off of the precharge transistors 504, 505, 509, 510 for the TIE cell nodes Y1, Y1N and Y0, Y0N. Variable timing for the rising edges of S and E accordingly allows a longer or shorter time to step up Y1 and Y0 following the rising edge of S and before the rising edge of E.

In turn, the two discharge circuits 322, 324 (for example in the form of discharge transistors 322, 324) are intended to discharge electric charge from the connection nodes 318, 320 during the precharging process.

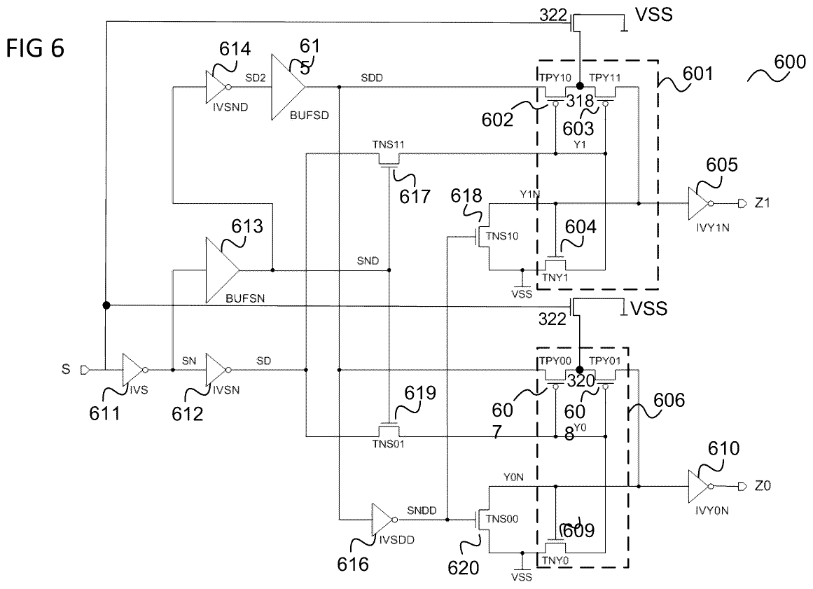

FIG. 6 shows a POC cell 600 according to another example.

Similarly to the POC cell 300 from FIG. 3, the POC cell 600 contains a first TIE cell 601, which is formed by a first p-channel FET 602 and a second p-channel FET 603 in series and a first n-channel FET 604 and is provided with a first output inverter 605, and a second TIE cell 606, which is formed by a third p-channel FET 607 and a fourth p-channel FET 608 in series and a second n-channel FET 609.

There is additionally also a circuit arrangement for forcing and releasing the non-equilibrium initial condition, containing a first input inverter 611 having an input S and an output SN, a second input inverter 612 having an input SN and an output SD, a first buffer 613 having an input SN and an output SND, a third input inverter 614 having an input SND and an output SD2, a second buffer 615 having an input SD2 and an output SDD, a fourth inverter 616 having an input SDD and an output SNDD, and (only nMOS) precharge transistors 617 to 620 for the TIE cell nodes Y1, Y1N, respectively Y0, Y0N.

By way of example, the first precharge n-channel FET 617 is supplied with SND at its gate and SD at its source and is coupled to Y1 at its drain, the second precharge n-channel FET 618 is supplied with SNDD at its gate and VSS at its source and is coupled to Y1N at its drain, the third precharge n-channel FET 619 is supplied with SND at its gate and SD at its source and is coupled to Y0 at its drain, and the fourth precharge n-channel FET 620 is supplied with SNDD at its gate and VSS at its source and is coupled to Y0N at its drain.

In this example too, the two discharge circuits 322, 324 (for example in the form of discharge transistors 322, 324) are intended to discharge electric charge from the connection nodes 318, 320 during the precharging process.

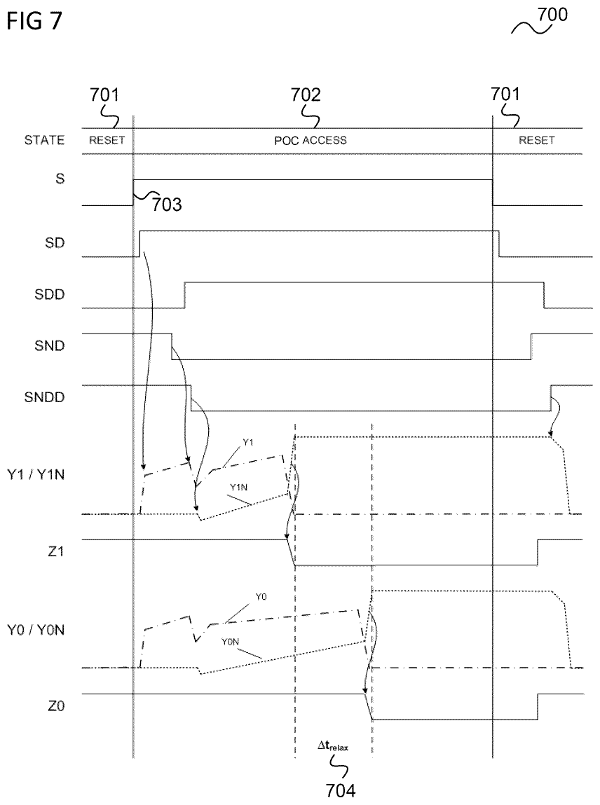

FIG. 7 shows a timing diagram 700 for the POC cell 600 from FIG. 6.

Similarly to FIG. 4, the signals S, SD, SDD, SND, SNDD, Y1, Y1N, Z1, Y0, Y0N, and Z0 are shown from left to right over time. As in FIG. 4, the signals for reset states 701 and a POC access state 702 are shown.

If the control input S is set to logic “0” (that is to say for example the VSS level, for example by a corresponding controller, for example the POC module 106), the TIE cell initial conditions

V(Y1)=VSS,V(Y1N)=VSS,

V(Y0)=VSS,V(Y0N)=VSS,

are forced, since the upper supply voltage (VDD in FIG. 3) of the TIE cells is replaced with SDD=logic “0”, and all of the precharge FETs 617, 618, 619 and 620 for the TIE cell nodes Y1, Y1N and Y0, Y0N are in their respective ON states (strong inversion).

This reset state is indicated in FIG. 7 as the initial state before the control input S is set to logic “1”, as a result of which the POC access is initiated. The POC access signal is then reset to logic “0”, causing the circuit to return to its reset state.

POC access is initiated on the rising edge 703 of S (S=logic “0”->logic “1”), as a result of which first SD, the precharge value for the nodes Y1 and Y0, changes to logic “1” (that is to say for example the VDD level), as a result of which the nodes Y1 and Y0 are stepped up to voltage levels of approximately ((VDD−Vth)(precharge FET 617), respectively (VDD−Vth)(precharge FET 619)), via the first precharge FET 617 and the third precharge FET 619, since the signal SND that controls the gates of these precharge FETs 617, 619 remains at the VDD level for a short time interval due to the first delay buffer 613. SND then changes to logic “0” and switches off the precharge FETs 617, 619 for the TIE cell nodes Y1 and Y0, as a result of which the node voltages thereof drop slightly by ΔVcc due to capacitive coupling of SND. Finally, SNDD changes to logic “0” and switches off the second precharge FET 618 and the fourth precharge FET 619 for the nodes Y1N and Y0N, as a result of which the node voltages thereof drop slightly by ΔVcc due to capacitive coupling of SNDD.

The relaxation of the node pairs Y1, Y1N and Y0, Y0N then takes place, but with different initial conditions: Y1 and Y0 start from (VDD−Vth(precharge FET 617)−ΔVcc), respectively (VDD−Vth(precharge FET 619)−ΔVcc)), and Y1N and Y0N start from VSS−ΔVcc′ instead of VSS. This first leads to generally smaller relaxation times (since the p-channel FETs 602, 603, 607, 608 of the TIE cells start in a comparatively less deep subthreshold state).

In addition and particularly importantly, negative feedback with reference to temperature variations is also implemented: since Vth(precharge FET 617) and Vth(precharge FET 619) increase as the temperature decreases, the starting values of the voltages at the nodes Y1 and Y0 decrease at lower temperatures, thereby increasing the relaxation speed and counteracting the decrease in the relaxation speed due to higher threshold voltages of the FETs 602, 603, 604, 607, 608, 609 of the TIE cells.

The extremely nonlinear relaxation from the deep subthreshold non-equilibrium state of the nodes Y1, Y1N and Y0, Y0N after the restrictions with S=1 (that is to say during the POC access phase 702) have been released is indicated in FIG. 7.

Due to production variations of the relevant transistors 602, 603, 604 (first TIE cell 601) and of the transistors 607, 608, 609 (second TIE cell 602), the electrothermal relaxations of Y1, Y1N and Y0, Y0N usually differ significantly in terms of their relaxation times (to an order of magnitude of a few ns to several 10 ns). As a result, the output signals Z1 and Z0 change to logic “1” at different times, this being indicated by a time difference 704, which is indicated as ΔtRelax in FIG. 7.

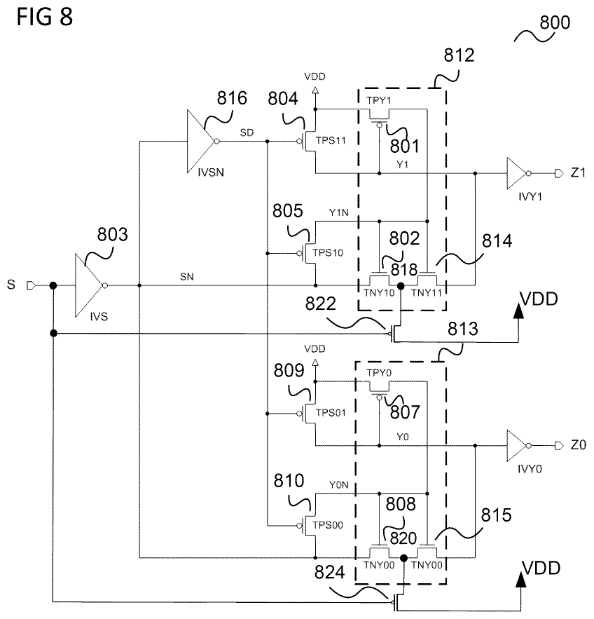

FIG. 8 shows a POC cell 800, which may be seen as the CMOS complement of the POC cell 300 from FIG. 3.

This means that the TIE cells 812, 813 are each formed by a p-channel FET 801, 807 and a series connection of n-channel FETs 802, 814, 808, 815 (instead of the other way around, as in FIG. 3) and the precharge FETs 804, 805, 809, 810 are p-channel FETs (instead of n-channel FETs).

The POC cell 800 also differs from the POC cell 300 in that it has a first input inverter 803, which receives the input signal S and outputs SN to the source of the second precharge FET 805 and the fourth precharge FET 810, and a second input inverter 816, which receives SN, inverts it to form SD and delivers SD to the gates of the precharge FETs 804 to 810.

The input inverters 803, 816 and the precharge FETs 804, 805 (for Y1 and Y1N) and 809, 810 (for Y0 and Y0N) form the circuit arrangement for forcing and releasing the non-equilibrium initial condition.

A third connection node 818 between the two series-connected seventh n-channel FET 802 and eighth n-channel FET 814 of the first TIE cell 812 is a floating node with an undefined electrical potential. Furthermore, a second connection node 820 between the two series-connected ninth n-channel FET 808 and tenth n-channel FET 815 of the second TIE cell 813 is also a floating node with an undefined electrical potential. These undefined electrical potentials increase the error rate within the POC cell 800.

According to various aspects of this disclosure, in order to reduce the error rate in the POC cell 300 in one or both TIE cells 812, 813, provision is made for a discharge circuit 822, 824, by way of which the previously undefined electrical potential at the third connection node 318 is fixed to a predetermined or predefined reference potential (for example the lower reference potential VSS, for example ground potential) during the precharge state of the POC cell 800.

By way of example, the first TIE cell 812 thus has a third discharge circuit 822 that is connected to the third connection node 318, on the one hand, and to the high reference potential VDD, on the other hand, and is configured for the controlled discharge of electric charge from the third connection node 318. The third discharge circuit 822 has a third discharge transistor (for example a p-channel FET) 822 or is formed thereby, the drain of which is connected (for example directly) to the third connection node 818 and the source of which is connected (for example directly) to the high reference potential VDD. The control terminal (for example gate) of the third discharge transistor 818 is connected (for example directly) to the input S and is driven by way of the control input S. The third discharge circuit 822 thus by way of illustration forms a switch that is closed during the precharging process of the POC cell 800, and electric charge located on the third connection node 818 is thus discharged to the high reference potential VDD. When the precharging process is complete, the switch is opened again, that is to say for example the third discharge transistor 822 is blocked and thus the third connection node 818 is electrically disconnected, for example isolated, from the high reference potential VDD.

By way of example, the second TIE cell 813 also has a fourth discharge circuit 824 that is connected to the fourth connection node 820, on the one hand, and to the high reference potential VDD, on the other hand, and is configured for the controlled discharge of electric charge from the fourth connection node 820. The fourth discharge circuit 824 has a fourth discharge transistor (for example a p-channel FET) 824 or is formed thereby, the drain of which is connected (for example directly) to the fourth connection node 820 and the source of which is connected (for example directly) to the high reference potential VDD. The control terminal (for example gate) of the fourth discharge transistor 820 is connected (for example directly) to the input S and is driven by way of the control input S. The fourth discharge circuit 824 thus by way of illustration likewise forms a switch that is closed during the precharging process of the POC cell 800, and electric charge located on the fourth connection node 820 is thus discharged to the high reference potential VDD. When the precharging process is complete, the switch is opened again, that is to say for example the fourth discharge transistor 824 is blocked and thus the fourth connection node 820 is electrically disconnected, for example isolated, from the high reference potential VDD.

As an alternative, the control terminals (for example gates) of the discharge transistors 822, 824 may also be connected to a separate terminal (that is to say not to the input S) and be driven by way of another control signal, but in such a way that the discharge transistors 822, 824 are closed during the precharging process and thus electrically conductively connect the respective connection node 818, 820 to the high reference potential VDD, and are open during normal operation (that is to say for example when generating a cryptographic secret key) and accordingly electrically isolate the respective connection node from the high reference potential VDD.

During the precharging process, the control input S is logic “0” (by way of illustration a low-level signal, for example 0 V). The third discharge transistor 822 and the fourth discharge transistor 824 are thus switched on, and possible electric charges located on the third connection node 818 and the fourth connection node 820 are discharged to the high reference potential VDD. In other words, the respective connection node 818, 820 is electrically conductively connected to the high reference potential VDD. In this case, the signal SN provided by the input inverter 803 is logic “1” (by way of illustration a high-level signal, for example 5 V). The p-channel FET 804 and the p-channel FET 805 of the first precharge control circuit arrangement are thus blocked, and the first TIE cell 812 is thus deactivated. Furthermore, the p-channel FET 809 and the p-channel FET 810 of the second precharge control circuit arrangement are likewise blocked, and the second TIE cell 813 is thus also deactivated.

As soon as the POC cell 800 is intended to be started in order to generate a secret (for example a cryptographic secret key), the control input S is set to logic “1” (by way of illustration a high-level signal, for example 5 V). The third discharge transistor 822 and the fourth discharge transistor 824 are thus electrically switched off and the third connection node 818 and/or the fourth connection node 820 are/is electrically isolated from the high reference potential VDD. In other words, the respective connection node 818, 820 is electrically isolated from the high reference potential VDD.

In this case, the signal SN provided by the input inverter 803 is logic “0” (by way of illustration a low-level signal, for example 0 V). The p-channel FET 804 and the p-channel FET 805 of the first precharge control circuit arrangement are thus switched on, and the first TIE cell 812 is thus activated. Furthermore, the p-channel FET 809 and the p-channel FET 810 of the second precharge control circuit arrangement are likewise switched on, and the second TIE cell 813 is thus also activated. However, the signal SN provided by the input inverter 803 is time-delayed with respect to the control input S (by the first buffer 316 and the input inverter 803) before the signal SN starts to generate the secret by way of the TIE cells 812, 813. This delay is dimensioned to be long enough for the third discharge transistor 818 and the fourth discharge transistor 820 to have enough time to terminate their respective switch-off operation.

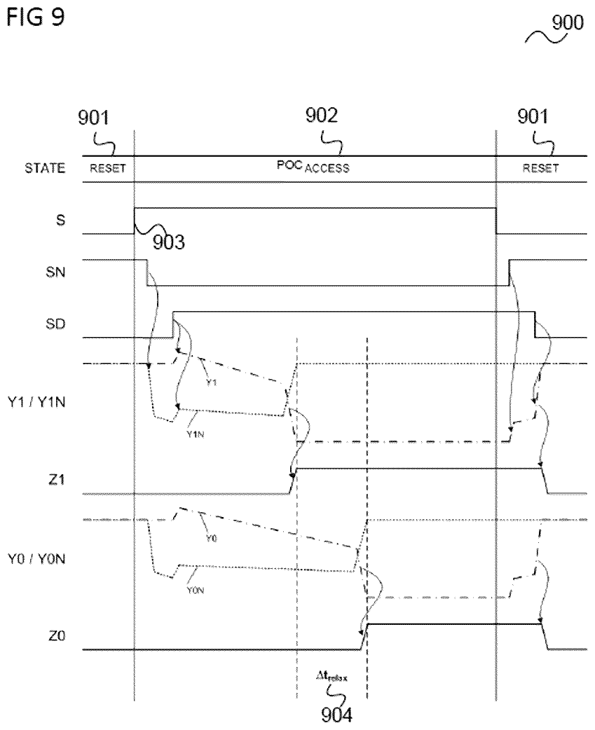

FIG. 9 shows a timing diagram 900 for the POC cell 800 from FIG. 8.

Similarly to FIG. 4 and FIG. 7, the signals S, SN, SD, Y1, Y1N, Z1, Y0, Y0N and Z0 are shown from left to right over time. As in FIG. 4 and FIG. 7, the signals for reset states 901 and a POC access state 902 are shown.

If the control input S is set to logic “0” (that is to say for example the VSS level), for example by a corresponding controller, for example the POC module 106, the TIE cell initial conditions

V(Y1)=VDD,V(Y1N)=VDD,

V(Y0)=VDD,V(Y0N)=VDD,
are forced, since the lower supply voltage (VSS in FIG. 3) of the TIE cells is replaced with SN=logic “1”, and all of the precharge FETs 804, 805, 809 and 810 for the TIE cell nodes Y1, Y1N and Y0, Y0N are in their respective ON states (strong inversion).

This reset state is indicated in FIG. 9 as the initial state before the control input S is set to logic “1”, as a result of which the POC access is initiated. The POC access signal is then reset to logic “0”, causing the circuit to return to its reset state.

The POC access is initiated on the rising edge 1303 of S (S=logic “0”->logic “1” of S), as a result of which first SN, the lower supply of the TIE cells 812, 813, changes to logic “0” (VSS level), such that the nodes Y1N and Y0N are stepped down to voltage levels of approximately |Vth(precharge FET 805)|, respectively |Vth(precharge FET 810)|, via the second precharge FET 805 and the fourth precharge FET 810.

Shortly afterwards, SD changes to logic “1” and switches off the precharge FETS 804, 805, 809, 810 for the TIE cell nodes Y1, Y1N and Y0, Y0N, as a result of which the node voltages thereof increase slightly by ΔVcc, respectively, ΔVcc′, due to capacitive coupling of SN.

The relaxation of the node pairs Y1, Y1N and Y0, Y0N then takes place, but with the following initial conditions: Y1N and Y0N no longer start from VSS, but from |Vth(precharge FET 805)|+ΔVcc, respectively |Vth(precharge FET 810)|+ΔVcc, and Y1 and Y0 start from VDD+ΔVcc′ instead of VDD.

This first leads to generally smaller relaxation times (since the n-channel FETs 802, 814, 808, 815 of the TIE cells start in a comparatively less deep subthreshold state).

In addition and particularly importantly, negative feedback with reference to temperature variations is also implemented: since |Vth(precharge FET 805)| and |Vth(precharge FET 810)| increase as the temperature decreases, the starting values of the voltages at the nodes Y1N and Y0N increase at lower temperatures, thereby increasing the relaxation speed and counteracting the decrease in the relaxation speed due to higher threshold voltages of the FETs 801, 802, 814, 807, 808, 815 of the TIE cells.

The extremely nonlinear relaxation from the deep subthreshold non-equilibrium state of the nodes Y1, Y1N and Y0, Y0N after the restrictions with S=logic “1” (that is to say during the POC access phase 902) have been released is indicated in FIG. 9.

Due to production variations of the relevant FETs 801, 802, 804 (of the first TIE cell 812) and of the FETs 807, 808, 815 (of the second TIE cell 813), the electrothermal relaxations of Y1, Y1N and Y0, Y0N usually differ significantly in terms of their relaxation times (to an order of magnitude of a few ns to several 10 ns). As a result, the output signals Z1 and Z0 change to logic “1” at different times, this being indicated by a time difference 904, which is indicated as ΔtRelax in FIG. 9.

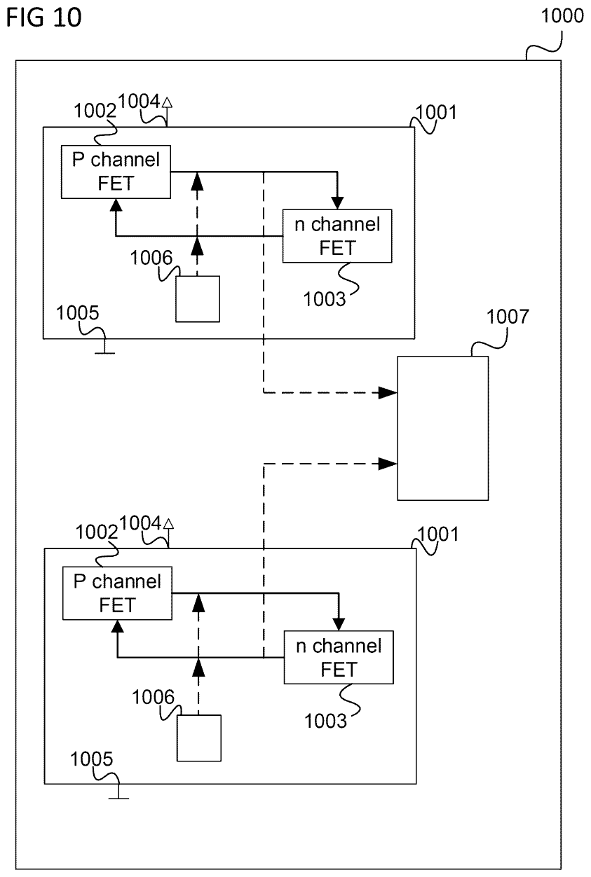

In summary, according to various embodiments, provision is made for a physically obfuscated circuit (POC), as illustrated in FIG. 10.

FIG. 10 shows a physically obfuscated circuit 1000 according to one embodiment.

The physically obfuscated circuit 1000 contains multiple subcircuits 1001, wherein each subcircuit 1001 contains at least one p-channel field-effect transistor 1002, at least one n-channel field-effect transistor 1003, a first power supply terminal 1004, which is configured to receive a first supply voltage with an upper supply potential, and a second power supply terminal 1005, which is configured to receive a second supply voltage with a lower supply potential.

The at least one p-channel field-effect transistor 1002 and the at least one n-channel field-effect transistor 1003 are connected such that the at least one n-channel field-effect transistor 1003, if it is supplied with the upper supply potential at its gate, delivers the lower supply potential to the gate of the at least one p-channel field-effect transistor 1002, and the at least one p-channel field-effect transistor 1002, if it is supplied with the lower supply potential at its gate, delivers the upper supply potential to the gate of the at least one n-channel field-effect transistor 1003.

Each subcircuit 1001 furthermore contains a precharge circuit 1006 that is configured to precharge the subcircuit to a first state in which the potential at the gate of the at least one n-channel field-effect transistor 1003 is lower than the upper supply potential and the potential at the gate of the at least one p-channel field-effect transistor 1002 is higher than the lower supply potential.

The physically obfuscated circuit 1000 furthermore contains a physically obfuscated circuit value bit generation circuit 1007, which generates at least one physically obfuscated circuit value bit depending on which of the subcircuits 1001 is the first to enter a second state in which the potential at the gate of the at least one n-channel field-effect transistor 1003 is the upper potential and the potential at the gate of the at least one p-channel field-effect transistor 1002 is the lower potential.

By way of example, the physically obfuscated circuit (POC) 1000 may correspond to the POC source 105 together with the POC module 106.

In other words, according to various embodiments, two (or more) TIE cells (which are referred to above as a “subcircuit”) each having at least one p-channel FET and at least one n-channel FET that keep one another in a steady state through mutual switch-on are each precharged to an inverse state. The inverse state is inverse to the steady state in the sense that the FETs are switched off. A POC bit is generated based on which TIE cell reaches its steady state first. If there are more than two TIE cells, multiple POC bits may be generated by the POC bit generation circuit based on the order in which the TIE cells reach the steady state.

The first state may be a state when the FETs are switched off, and the second state may be a state when the FETs are switched on. It should be noted that there may be a “relaxation state” between the first state and the second state, that is to say a state that each subcircuit has when it transitions from the first state to the second state. The first state (possibly together with the relaxation state) may be considered to be a “non-equilibrium” state.

By way of example, the relaxation state of a subcircuit starts when the precharge circuit completes the precharging of the circuit, that is to say releases the subcircuit from the first state (which is forced by the precharging). By way of example, in the first state, the precharge circuit forces the subcircuit to be in (and remain in) the first state and “then releases the subcircuit” for it to transition to its second state. The subcircuits may then be seen as “in a race” to the second state, and the POC bit generation circuit generates one or more POC bits based on which subcircuit “wins the race” (or in the case of more than two TIE cells, possibly based on the order in which the TIE cells complete the respective relaxation).

Various aspects of the disclosure are explained below:

Example 1 is a physically obfuscated circuit. The physically obfuscated circuit has multiple subcircuits, wherein each subcircuit comprises the following: multiple series-connected transistors of a first conductivity type; and at least one transistor of a second conductivity type different from the first conductivity type. The transistors are connected such that the multiple series-connected transistors of the first conductivity type, if they are supplied with a first reference potential at their respective control terminal, deliver a second reference potential different from the first reference potential to the control terminal of the at least one transistor of the second conductivity type; and that the at least one transistor of the second conductivity type, if it is supplied with a second reference potential at its control terminal, delivers the first reference potential to the control terminal of each transistor of the multiple series-connected transistors of the first conductivity type. The physically obfuscated circuit furthermore has a precharge circuit that is configured to precharge the subcircuit to a first state in which the potential at the control terminal of the at least one transistor of the second conductivity type is different from the second reference potential and the potential at the control terminal of each of the multiple series-connected transistors of the first conductivity type is different from the first reference potential. The physically obfuscated circuit furthermore has a physically obfuscated circuit value bit generation circuit that generates at least one physically obfuscated circuit value bit depending on which of the subcircuits is the first to enter a second state in which the potential at the control terminal of the at least one transistor of the second conductivity type is the second reference potential and the potential at the control terminal of each of the multiple series-connected transistors of the first conductivity type is the first reference potential. At least one subcircuit of the multiple subcircuits has a discharge circuit that is connected to a connection node between two transistors of the multiple series-connected transistors of the first conductivity type for the controlled discharge of electric charge from the connection node.

In example 2, the subject matter of example 1 may optionally have the feature that the second reference potential is higher than the first reference potential; and that the precharge circuit is configured to precharge the subcircuit to the first state in which the potential at the control terminal of the at least one transistor of the second conductivity type is lower than the second reference potential and the potential at the control terminal of each of the multiple series-connected transistors of the first conductivity type is higher than the first reference potential.

In example 3, the subject matter of example 2 may optionally have the feature that the first conductivity type is a p-conductivity type; and that the second conductivity type is an n-conductivity type.

In example 4, the subject matter of example 1 may optionally have the feature that the second reference potential is lower than the first reference potential; and that the precharge circuit is configured to precharge the subcircuit to the first state in which the potential at the control terminal of the at least one transistor of the second conductivity type is higher than the second reference potential and the potential at the control terminal of each of the multiple series-connected transistors of the first conductivity type is lower than the first reference potential.

In example 5, the subject matter of example 4 may optionally have the feature that the first conductivity type is an n-conductivity type; and that the second conductivity type is a p-conductivity type.

In example 6, the subject matter of any one of examples 1 to 5 may optionally have the feature that each subcircuit of the multiple subcircuits has a discharge circuit that is connected to a connection node between two transistors of the multiple series-connected transistors of the first conductivity type for the controlled discharge of electric charge from the connection node.

In example 7, the subject matter of any one of examples 1 to 6 may optionally have the feature that the discharge circuit has a switch that connects the connection node to the first reference potential or isolates it from the first reference potential.

In example 8, the subject matter of example 7 may optionally have the feature that the switch has a transistor of the second conductivity type or is formed thereby.

In example 9, the subject matter of any one of examples 1 to 8 may optionally have the feature that the at least one transistor of the second conductivity type has multiple series-connected transistors of the second conductivity type.

In example 10, the subject matter of example 9 may optionally have the feature that at least one subcircuit of the multiple subcircuits has an additional discharge circuit that is connected to an additional connection node between two transistors of the multiple series-connected transistors of the second conductivity type for the controlled discharge of electric charge from the additional connection node.

In example 11, the subject matter of any one of examples 1 to 10 may optionally have the feature that the precharge circuit is configured to allow the start of a transition of the subcircuit from the first state to the second state following the precharging of the subcircuit to the first state.

In example 12, the subject matter of any one of examples 1 to 11 may optionally have the feature that the precharge circuit is configured to allow the start of a transition of the subcircuits from the first state to the second state by way of delivering a common input signal to the subcircuits.

In example 13, the subject matter of any one of examples 1 to 12 may optionally have the feature that the precharge circuit is configured to precharge the circuit to the first state in response to receiving a request for a physically obfuscated circuit value.

In example 14, the subject matter of any one of examples 1 to 13 may optionally have the feature that the second state is a steady state of the subcircuit and the first state is an inverse state of the second state.

In example 15, the subject matter of any one of examples 1 to 14 may optionally have the feature that, in the first state, the potential at the control terminal of the at least one transistor of the second conductivity type is the first reference potential and the potential at the control terminal of each of the multiple series-connected transistors of the first conductivity type is the second reference potential.

In example 16, the subject matter of any one of examples 1 to 15 may optionally have the feature that, in the first state, the potential at the control terminal of the at least one transistor of the second conductivity type is a potential for switching off the at least one transistor of the second conductivity type and the potential at the control terminal of each of the multiple series-connected transistors of the first conductivity type is a potential for switching off each of the multiple series-connected transistors of the first conductivity type.

In example 17, the subject matter of any one of examples 1 to 16 may optionally have the feature that the physically obfuscated circuit value bit generation circuit is configured to receive, from each subcircuit, a signal indicating the state of the subcircuit.

In example 18, the subject matter of example 14 may optionally have the feature that the physically obfuscated circuit value bit generation circuit comprises a latch circuit that is supplied with the signal indicating the state of the subcircuit by each subcircuit and is configured to be switched depending on which of the subcircuits is the first to enter the second state.

In example 19, the subject matter of any one of examples 1 to 18 may optionally have the feature that the multiple subcircuits comprise three or more subcircuits and the physically obfuscated circuit value bit generation circuit is configured to generate multiple physically obfuscated circuit value bits depending on an order in which the subcircuits enter the second state.

In example 20, the subject matter of any one of examples 1 to 19 may optionally have the feature that the physically obfuscated circuit furthermore has a key generator that is configured to generate a cryptographic key based on the physically obfuscated circuit value bit.

In example 21, the subject matter of any one of examples 1 to 20 may optionally have the feature that, in the first state, the potential at the control terminal of the at least one transistor of the second conductivity type depends on a transistor threshold voltage of a transistor of the precharge circuit.

In example 22, the subject matter of any one of examples 1 to 21 may optionally have the feature that, in the first state, the potential at the control terminal of each transistor of the multiple series-connected transistors of the first conductivity type depends on a transistor threshold voltage of a transistor of the precharge circuit.

In example 23, the subject matter of any one of examples 1 to 22 may optionally have the feature that, in the first state, the potential at the control terminal of the at least one transistor of the second conductivity type is the first operating potential plus or minus a transistor threshold voltage of a transistor of the precharge circuit.

In example 24, the subject matter of any one of examples 1 to 23 may optionally have the feature that, in the first state, the potential at the control terminal of each transistor of the multiple series-connected transistors of the first conductivity type is the second operating potential plus or minus a transistor threshold voltage of a transistor of the precharge circuit.

1. A physically obfuscated circuit, comprising:
multiple subcircuits, wherein each subcircuit comprises the following:
multiple series-connected transistors of a first conductivity type;
at least one transistor of a second conductivity type different from the first conductivity type;
wherein the transistors are connected such that
the multiple series-connected transistors of the first conductivity type, if they are supplied with a first reference potential at their respective control terminal, deliver a second reference potential different from the first reference potential to the control terminal of the at least one transistor of the second conductivity type; and
the at least one transistor of the second conductivity type, if it is supplied with a second reference potential at its control terminal, delivers the first reference potential to the control terminal of each transistor of the multiple series-connected transistors of the first conductivity type; and
a precharge circuit that is configured to precharge the subcircuit to a first state in which the potential at the control terminal of the at least one transistor of the second conductivity type is different from the second reference potential and the potential at the control terminal of each of the multiple series-connected transistors of the first conductivity type is different from the first reference potential;
a physically obfuscated circuit value bit generation circuit configured to generate at least one physically obfuscated circuit value bit depending on which of the subcircuits is first to enter a second state in which the potential at the control terminal of the at least one transistor of the second conductivity type is the second reference potential and the potential at the control terminal of each of the multiple series-connected transistors of the first conductivity type is the first reference potential; and
wherein at least one subcircuit of the multiple subcircuits has a discharge circuit that is connected to a connection node between two transistors of the multiple series-connected transistors of the first conductivity type for the controlled discharge of electric charge from the connection node.

2. The physically obfuscated circuit as claimed in claim 1,
wherein the second reference potential is higher than the first reference potential, and
wherein the precharge circuit is configured to precharge the subcircuit to the first state in which the potential at the control terminal of the at least one transistor of the second conductivity type is lower than the second reference potential and the potential at the control terminal of each of the multiple series-connected transistors of the first conductivity type is higher than the first reference potential.

3. The physically obfuscated circuit as claimed in claim 2,
wherein the first conductivity type is a p-conductivity type, and
wherein the second conductivity type is an n-conductivity type.

4. The physically obfuscated circuit as claimed in claim 1,
wherein the second reference potential is lower than the first reference potential, and
wherein the precharge circuit is configured to precharge the subcircuit to the first state in which the potential at the control terminal of the at least one transistor of the second conductivity type is higher than the second reference potential and the potential at the control terminal of each of the multiple series-connected transistors of the first conductivity type is lower than the first reference potential.

5. The physically obfuscated circuit as claimed in claim 4,
wherein the first conductivity type is an n-conductivity type, and
wherein the second conductivity type is a p-conductivity type.

6. The physically obfuscated circuit as claimed in claim 1,
wherein each subcircuit of the multiple subcircuits has a discharge circuit that is connected to a connection node between two transistors of the multiple series-connected transistors of the first conductivity type for the controlled discharge of electric charge from the connection node.

7. The physically obfuscated circuit as claimed in claim 1,
wherein the discharge circuit has a switch that connects the connection node to the first reference potential or isolates it from the first reference potential.

8. The physically obfuscated circuit as claimed in claim 7,
wherein the switch has a transistor of the second conductivity type or is formed thereby.

9. The physically obfuscated circuit as claimed in claim 1,
wherein the at least one transistor of the second conductivity type has multiple series-connected transistors of the second conductivity type.

10. The physically obfuscated circuit as claimed in claim 9,
wherein at least one subcircuit of the multiple subcircuits has an additional discharge circuit that is connected to an additional connection node between two transistors of the multiple series-connected transistors of the second conductivity type for the controlled discharge of electric charge from the additional connection node.

11. The physically obfuscated circuit as claimed in claim 1,
wherein the precharge circuit is configured to allow a start of a transition of the subcircuit from the first state to the second state following the precharging of the subcircuit to the first state.

12. The physically obfuscated circuit as claimed in one claim 1,
wherein the precharge circuit is configured to allow a start of a transition of the subcircuits from the first state to the second state by way of delivering a common input signal to the subcircuits.

13. The physically obfuscated circuit as claimed in claim 1,
wherein the precharge circuit is configured to precharge the circuit to the first state in response to receiving a request for a physically obfuscated circuit value.

14. The physically obfuscated circuit as claimed in claim 1,
wherein the second state is a steady state of the subcircuit and the first state is an inverse state of the second state.

15. The physically obfuscated circuit as claimed in claim 1,
wherein, in the first state, the potential at the control terminal of the at least one transistor of the second conductivity type is the first reference potential and the potential at the control terminal of each of the multiple series-connected transistors of the first conductivity type is the second reference potential.

16. The physically obfuscated circuit as claimed in claim 1,
wherein, in the first state, the potential at the control terminal of the at least one transistor of the second conductivity type is a potential for switching off the at least one transistor of the second conductivity type and the potential at the control terminal of each of the multiple series-connected transistors of the first conductivity type is a potential for switching off each of the multiple series-connected transistors of the first conductivity type.

17. The physically obfuscated circuit as claimed in claim 1,
wherein the physically obfuscated circuit value bit generation circuit is configured to receive, from each subcircuit, a signal indicating the state of the subcircuit.

18. The physically obfuscated circuit as claimed in claim 14,
wherein the physically obfuscated circuit value bit generation circuit comprises a latch circuit that is supplied with a signal indicating the state of the subcircuit by each subcircuit and is configured to be switched depending on which of the subcircuits is the first to enter the second state.

19. The physically obfuscated circuit as claimed in claim 1,
wherein the multiple subcircuits comprise three or more subcircuits and the physically obfuscated circuit value bit generation circuit is configured to generate multiple physically obfuscated circuit value bits depending on an order in which the subcircuits enter the second state.

20. The physically obfuscated circuit as claimed in claim 1, further comprising:
a key generator that is configured to generate a cryptographic key based on the physically obfuscated circuit value bit.

21. The physically obfuscated circuit as claimed in claim 1,
wherein, in the first state, a potential at the control terminal of the at least one transistor of the second conductivity type depends on a transistor threshold voltage of a transistor of the precharge circuit.

22. The physically obfuscated circuit as claimed in claim 1,
wherein, in the first state, a potential at the control terminal of each transistor of the multiple series-connected transistors of the first conductivity type depends on a transistor threshold voltage of a transistor of the precharge circuit.

23. The physically obfuscated circuit as claimed in claim 1,
wherein, in the first state, a potential at the control terminal of the at least one transistor of the second conductivity type is the first operating potential plus or minus a transistor threshold voltage of a transistor of the precharge circuit.

24. The physically obfuscated circuit as claimed in claim 1,
wherein, in the first state, a potential at the control terminal of each transistor of the multiple series-connected transistors of the first conductivity type is the second operating potential plus or minus a transistor threshold voltage of a transistor of the precharge circuit.
